(19) United States
(12) Patent Application Publication
(10) Pub. No.: US 2022/0372891 A1
(43) Pub. Date: Nov. 24, 2022

(54) METHOD FOR STABILITY ANALYSIS OF COMBUSTION CHAMBER OF GAS TURBINE ENGINE BASED ON IMAGE SEQUENCE ANALYSIS

(71) Applicant: DALIAN UNIVERSITY OF TECHNOLOGY, Dalian, Liaoning (CN)

(72) Inventors: Ximing SUN, Dalian, Liaoning (CN); Qi TANG, Dalian, Liaoning (CN); Hongyang ZHAO, Dalian, Liaoning (CN); Fuxiang QUAN, Dalian, Liaoning (CN); Ziyao DING, Dalian, Liaoning (CN); Di GUO, Dalian, Liaoning (CN)

(21) Appl. No.: 17/606,180

(22) PCT Filed: Jan. 14, 2021
(86) PCT No.: PCT/CN2021/071766

§ 371 Date: Oct. 25, 2021

(51) Int. Cl. F01D 21/00; G06F 30/28

(52) U.S. Cl. CPC F01D 21/003; G06F 30/28; F05D 2260/81; F05D 2270/44; F05D 2270/709; F05D 2270/8041

(57) ABSTRACT

A method for stability analysis of a combustion chamber of a gas turbine engine based on image sequence analysis belongs to the field of fault prediction and health management of aeroengine. Firstly, flow field data inside a combustion chamber of a gas turbine engine is acquired. Secondly, flow field images of the combustion chamber are preprocessed to respectively obtain a discrimination model data set and a prediction model data set. Then, a 3DWaveNet model is constructed as a generation network of a prediction model. A discrimination network of the module is constructed. The generation network and the discrimination network are combined to form the prediction model. Finally, a discrimination model is constructed according to the discrimination model data set; the training set in the discrimination model data set is used for training, and the test set is used for assessment.

### TECHNICAL FIELD

The present invention relates to a method for stability analysis of a combustion chamber of a gas turbine engine based on image sequence analysis, and belongs to the field of fault prediction and health management of aero-engine.

### BACKGROUND

The aero-engine is in an operation environment with high temperature, high speed and heavy load for a long time, so the engine is liable to various faults. A combustion chamber is one of the key components of the aero-engine. Because the working state of the aero-engine changes greatly in a short time, the combustion chamber will be alternately in oil-poor and oil-rich working states in a very short time, thereby resulting in the instability of combustion. The fault of the combustion chamber will seriously damage the engine, so it is hoped to predict and analyze the working state of the combustion chamber before the fault occurs to realize timely maintenance before reaching the performance lower limit.

Traditional fault prediction for the combustion chamber is based on time series data measured by various sensors, which has certain delay and measurement errors, thereby causing the problems of hysteresis and poor accuracy in prediction. As original data, the flow field distribution inside the combustion chamber can best characterize the engine running state. The analytic processing of the flow field distribution images, rather than on the basis of time series data such as gas path parameters, can reserve the original information to the maximum extent, thereby improving prediction and analysis abilities.

The traditional time series image prediction techniques include the single mass center tracking method, the optical flow method and the like, which need to preprocess the images manually, thereby causing loss of partial information and generating inaccurate prediction results.

### SUMMARY

Aiming at low prediction accuracy in the prior art, the present invention provides a method for stability analysis of a combustion chamber of a gas turbine engine based on image sequence analysis through application of deep learning.

To achieve the above purpose, the present invention adopts the following technical solution:

A method for stability analysis of a combustion chamber of a gas turbine engine based on image sequence analysis comprises the following steps:

S1. acquiring flow field data inside a combustion chamber of a gas turbine engine, comprising the following steps:

S1.1 Considering that particle image velocimetry (PIV) equipment is difficult to obtain, simulating a flow field of the combustion chamber by computational fluid dynamics (CFD).

S1.2 Sampling a simulation process at an equal time interval to obtain a single frame image, wherein 30 frames are sampled per second.

S2. Preprocessing flow field images of the combustion chamber, comprising the following steps:

S2.1 Considering that combustion is a dynamic process and various random disturbances exist, conducting weighted average on the images at first, continuously taking a plurality of images in a small time interval, and using average results to characterize the image properties in the time period, with a calculation formula as follows:

$$\overline{{I}_{t}} ( x , y ) = \frac{1}{N} {\sum }_{j = 1}^{N} {w}_{j} {I}_{j} ( x , y )$$

in the formula, N is number of observations, which is 3 in the method; Iⱼ(x, y) is an instantaneously collected image at moment j; [symbol] (x, y) is an average image at moment t; and wⱼ is a weight coefficient and can be determined by Gaussian distribution.

S2.2 Denoising the images obtained by weighted average, to obtain clearer flow field images, wherein median filtering is used in the method, a window of 3×3is used for slide, pixel values in the window are sequenced and a median value is taken to replace the original gray level of the window center pixel.

S2.3 Storing the denoised images in the form of a matrix and converting the images into floating point tensors to obtain an image set; and to save computation, normalizing the pixel values and divided by 255.

S2.4 Labeling each image in the image set obtained in step S2.3 with “0” and “1” according to whether the flow field state of the image set is stable, with “0” representing instable and “1” representing normal, to construct a discrimination model data set.

S2.5 Disrupting the order in the discrimination model data set and then dividing the discrimination model data set into a training set and a test set according to a ratio of 4:1.

S2.6 Constructing the sample set using a window of size 129 on the image set obtained in step S2.3, and constructing a prediction model data set by using data falling in the window as a sample, using the first 128 data of each sample as input and using the last data as output.

S2.7 Disrupting the order in the prediction model data set and then dividing the prediction model data set into a training set and a test set according to a ratio of 4:1.

S3. Constructing a 3DWaveNet model as a generation network of a prediction model, comprising the following steps:

S3.1 Adjusting the dimension of each sample as (n_steps,rows,cols,1) as input of the generation network; wherein n steps is a time step; in the present invention, n_steps=128, which is input data dimension of the prediction model data set obtained in step S2.6; rows indicates the number of rows of the images; cols indicates the number of columns of the images; the flow field images are black and white images, and the number of channels is 1.

S3.2 Building a dilated convolution module based on causal convolution and dilated convolution, using 3D convolution to add a time dimension to capture and use residual connection to ensure that gradients do not disappear, introducing gated activation, reserving the features of each layer through skip connection and finally combining and outputting the features, and outputting a frame image.

S3.3 Using a mean square error (MSE) as a loss function for training the network, with the calculation formula as follows:

$${L}_{mse} = \frac{1}{Q} {\sum }_{n = 1}^{Q} {\sum }_{i = 1}^{rows} {\sum }_{j = 1}^{cols} {( {x}_{i , j}^{n} - )}^{2}$$

in the formula, Q is the number of training set samples, x_{i,j}ⁿ is a pixel value of point (i,j) on the nth real image, [symbol] is the nth image generated by generation network, and Lₘₛₑ is the loss function.

S4. Constructing a discrimination network of the prediction model, comprising the following steps:

S4.1 to ensure that the discrimination network of the prediction model can process the data from the output of step S3.2, keeping the input dimension of the network consistent with the output dimension of step S3.2. Conducting feature extraction using convolutional layers, and to ensure that the input of each layer of neural network has the same distribution, adding a batch standardization layer behind each convolutional layer.

S4.2 Outputting a probability value using sigmoid function by a fully connected layer to characterize the probability that the input images are used as real images.

S4.3 Using a binary cross entropy loss function as a loss function for training the network.

S5. Combining the generation network and the discrimination network to form the prediction model, comprising the following steps:

S5.1 Setting a discriminator to be untrainable; and after the input sample of the prediction model data set obtained in step S2.6 is input into a generator, inputting the generated images into the discrimination network to construct a prediction model network.

S5.2 Training the prediction model network using the training set in the prediction model data set obtained in step S2.7, and assessing the model using the test set after the number of training is ended.

S6. Constructing a discrimination model, comprising the following steps:

S6.1 Taking the discrimination model data set obtained in step S2.4 as the input of the discrimination model, using the convolutional layers to extract image features, adding a maximum pooling layer to reduce the dimension of data while preserving the regional features of the images, and adding a dropout layer to avoid overfitting.

S6.2 Using sigmoid function as an activation function to output a probability value to characterize whether the flow field of the combustion chamber is normal.

S6.3 Using the training set obtained in step S2.5 to train the discrimination model, and using the test set to evaluate the discrimination model.

S6.4 Finally inputting prediction images generated by the prediction model into the trained discrimination model to obtain a probability that the current state can operate normally.

The present invention has the beneficial effects: compared with the traditional method of stability analysis based on time series data, the present invention analyzes the stability of the combustion chamber through the method based on image sequence prediction and the original data can include more information, making the analysis more accurate. Another innovation is that the 3D convolutional module is used in the WaveNet framework, which can capture the temporal and spatial information of the image frame, thereby facilitating the processing of the time series image data. At the same time, the idea of a generative adversarial network is used in the construction of the overall network structure, and the discriminator is added to the prediction model to train the generator to obtain more real generated images. The generated prediction images are input into the discrimination model to obtain a probability that the current state can operate stably and can be regulated by different measures according to the size of the probability value, so as to conduct stability analysis. The present invention innovatively applies the image sequence prediction technology to the stability analysis of the combustion chamber, and can effectively improve the accuracy and stability of prediction.

### DESCRIPTION OF DRAWINGS

FIG. 1 is a flow chart of a method for stability analysis of a combustion chamber of a gas turbine engine based on image sequence prediction and analysis;

FIG. 2 is a flow chart of data preprocessing;

FIG. 3 is a structural diagram of a 3DWaveNet network;

FIG. 4 is a structural diagram of a discrimination network of a prediction model;

FIG. 5 is a structural diagram of a prediction model with a discrimination network; and

FIG. 6 is a structural diagram of a network of a discrimination model.

### DETAILED DESCRIPTION

The present invention is further described below in combination with the drawings. The present invention replies on the flow field images of a combustion chamber of a turbine engine with CFD numerical simulation. A flow of a method for stability analysis of the combustion chamber of a gas turbine engine based on image sequence analysis is shown in FIG. 1.

S1. Acquiring flow field data inside the combustion chamber of the gas turbine engine, comprising the following steps:

S1.1 Using CFD for flow field simulation of the combustion chamber, having images consistent with the results obtained by PIV experiment in certain features and having the capacity for serving as approximate values of real data, so that CFD simulation is used for data acquisition;

S1.2 Sampling a simulation process at an equal time interval to obtain a single frame image, wherein 30 frames are sampled per second in the present invention.

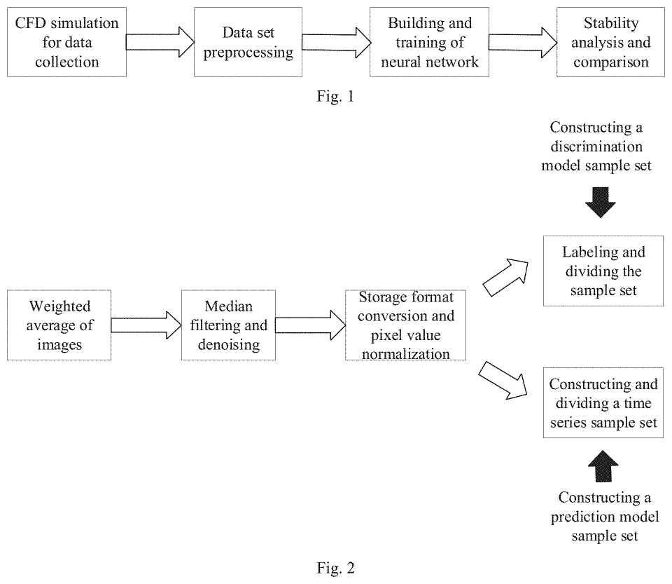

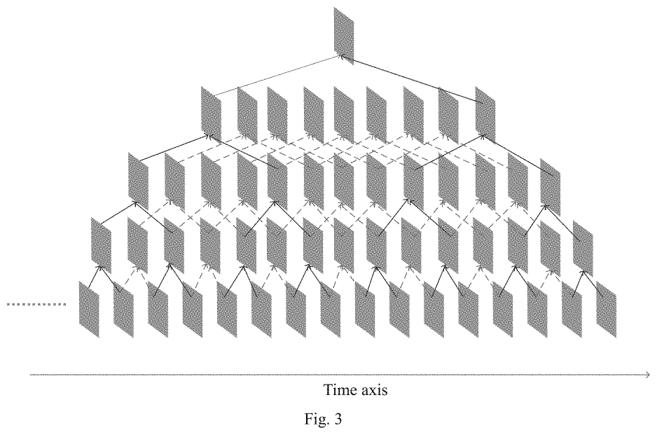

S2. Preprocessing flow field images of the combustion chamber. FIG. 2 is a flow chart of data preprocessing, with the data preprocessing steps as follows:

S2.1 Considering that combustion is a dynamic process with various random disturbances and no ideal stationary flow field exists, to obtain stable images of the flow field at a moment, continuously taking a plurality of images in a small time interval in the present invention, and using average results to characterize the image properties in the time period, with a calculation formula as follows:

$$\overline{{I}_{t}} ( x , y ) = \frac{1}{N} {\sum }_{j = 1}^{N} {w}_{j} {I}_{j} ( x , y )$$

In the formula, N is number of observations, which is 3 in the method; (x, y) is an instantaneously collected image at moment j; [symbol] (x, y) is an average image at moment t; and wⱼ is a weight coefficient and can be determined by Gaussian distribution.

S2.2 Denoising the images obtained by weighted average, to obtain clearer flow field images, wherein median filtering is used in the method, a window of 3×3 is used for slide, pixel values in the window are sequenced and a median value is taken to replace the original gray level of the window center pixel. To ensure that the sizes of the denoised images are unchanged, the edges of the images are filled with zero.

S2.3 Storing the denoised images in the form of a matrix and converting the images into floating point tensors; and to save computation, normalizing the pixel values and divided by 255.

S2.4 Labeling each frame of image obtained in S2.3 with “0” and “1” according to whether the flow field state of the image is stable, with “0” representing instable and “1” representing normal, to construct a discrimination model data set;

S2.5 Disrupting the order in the discrimination model data set and then dividing the discrimination model data set into a training set and a test set according to a ratio of 4:1;

S2.6 Constructing the sample set using a window of size 129 on the image set obtained in S2.3, and constructing a prediction model data set by using data falling in the window as a sample, using the first 128 data of each sample as input and using the last data as output;

S2.7 Disrupting the order in the prediction model data set and then dividing the prediction model data set into a training set and a test set according to a ratio of 4:1.

S3. Constructing a 3DWaveNet model as a generation network of a prediction model. FIG. 3 is a structural diagram of a 3DWaveNet network. The steps of constructing the 3DWaveNet network are as follows:

S3.1 Adjusting the dimension of each sample as (n_steps,rows,cols,1) as input of the 3DWaveNet network module, wherein n steps is a time step; in the present invention, n_steps=128, which is input data dimension of the prediction model data set obtained in S2.6; rows indicates the number of rows of the images; cols indicates the number of columns; the flow field images are represented by motion patterns and are black and white images, and the number of channels is 1.

S3.2 Building a dilated convolution module based on causal convolution and dilated convolution. FIG. 3 only shows part of the dilated convolution network layer. In the present invention, two identical dilated convolution modules are set. The dilated factor of each dilated convolution module is increased progressively in the form of 2ⁿ, and the maximum dilated factor is 64. A 3D convolution module is set as (2,3,3), wherein 2 represents a time step, the window of 3×3 is used for sliding, and 32 filters are used for each layer of convolution. Residual and skip connection is used in each layer to ensure that the gradient can flow for a long time to increase convergence speed. The extracted features are gradually advanced through layer-by-layer convolution. The features located at the bottom layer are effectively stored through skip connection to obtain abundant feature information. Gated activation units are introduced in each layer of convolution to choose the information effectively, with the specific formula:

z=tanh(W_{f,k}*x)⊙σ(W_{g,k}*x)

in the formula, tanh represents a hyperbolic tangent activation function, σ represents a sigmoid function, * represents a convolution operator, ⊙ represents an element-by-element multiplication operator, k represents the number of layers, and W represents a learnable convolution kernel.

S3.3 Using a mean square error (MSE) as a loss function for training the network, with the calculation formula as follows:

$${L}_{mse} = \frac{1}{Q} {\sum }_{n = 1}^{Q} {\sum }_{i = 1}^{rows} {\sum }_{j = 1}^{cols} {( {x}_{i , j}^{n} - )}^{2}$$

in the formula, Q is the number of training set samples, x_{i,j}ⁿ is a pixel value of point (i,j) on the nth real image, [symbol] is the nth image generated by generation network, and Lₘₛₑ is the loss function.

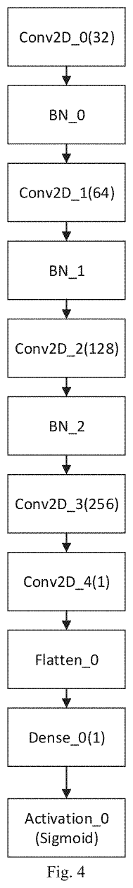

S4. Constructing a discrimination network of the prediction model. FIG. 4 is a structural diagram of a discrimination network, comprising the following steps:

S4.1 To ensure that the discrimination network of the prediction model can process the data from the output of S3.2, keeping the input dimension of the network consistent with the output dimension of S3.2. Conducting feature extraction using convolutional layers, and to ensure that each layer of neural network has the same distribution, introducing a batch standardization layer behind each convolutional layer, normalizing the input data to the normal distribution of zero-mean unit variance to prevent the gradient from disappearing, and using Leaky ReLU as an activation function to ensure that a negative derivative still exists, with the specific formula:

$${y}_{i} = \{ \begin{matrix}{x}_{i} {x}_{i} \geq 0 \\ \frac{{x}_{i}}{{a}_{i}} {x}_{i} < 0\end{matrix}$$

In the formula, xᵢ is input, yᵢ is output and αᵢ is a parameter greater than 1.

S4.2 Outputting a probability value finally using sigmoid function as the activation function by a fully connected layer to characterize the probability that the input images are used as real images;

S4.3 Using a binary cross entropy loss function as a loss function for training the network.

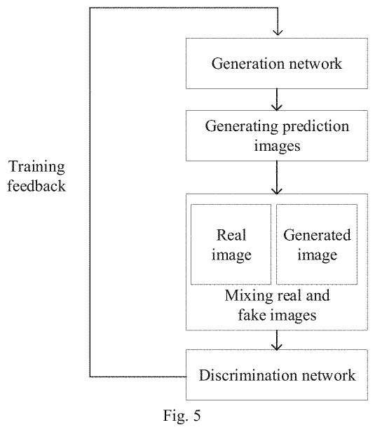

S5. Combining the generation network and an adversarial network to form the prediction model. FIG. 5 is a structural diagram of a prediction model with the adversarial network, comprising the following steps:

S5.1 Setting a discriminator to be in an untrainable mode firstly; and after the input sample of the prediction model data set obtained in S2.6 is input into a generator, inputting the generated images into the discriminator to construct a prediction model network;

S5.2 Individually training the discriminator, inputting the training set in the prediction model data set obtained in S2.7 into the generator to generate prediction images and label the images with “0” representing the generated images, labeling the corresponding real images (output data in the training set) with “1”, mixing the real and fake images and adding noise to the labels, and then training the discriminator;

S5.3 Setting the discriminator to be untrainable; training the whole prediction model network; inputting the input data of the training set obtained in S2.7 into the prediction network; setting output labels as “1”, i.e., expecting that the discrimination network judges the prediction images generated by the generation network as the real images, and alternately training the generation network and the discrimination network and repeating in this way until the number of training ends; assessing the prediction model using the test set obtained by S2.7, i.e., expecting the accuracy of the discrimination network to be about 50% to prove that the images generated by the generation network are real so that the discrimination network cannot make differentiation.

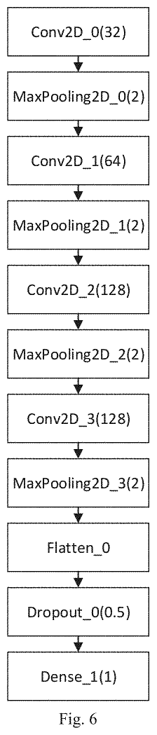

S6. Constructing a discrimination model. FIG. 6 is a structural diagram of a network of the discrimination model, comprising the following steps:

S6.1 Taking the discrimination model data set obtained in S2.4 as the input of the model and the corresponding “0” and “1” labels as the output, using the convolutional layers to extract image features, adding a maximum pooling layer to reduce the dimension of data while preserving the regional features of the images, and adding a dropout layer to avoid overfitting, with a binary cross entropy function as the loss function;

S6.2 Using sigmoid function as the activation function to output a probability value to characterize whether the flow field of the combustion chamber is normal;

S6.3 Using the training set obtained in S2.5 to train the discrimination model, and using the test set to evaluate the model;

S6.4 Inputting the prediction images generated by the prediction model into the trained discrimination model to obtain a probability that the current state can operate normally (is stable or not); and taking different measures for control through the size of the probability value.

The above embodiments only express the implementation of the present invention, and shall not be interpreted as a limitation to the scope of the patent for the present invention. It should be noted that, for those skilled in the art, several variations and improvements can also be made without departing from the concept of the present invention, all of which belong to the protection scope of the present invention.

1. A method for stability analysis of a combustion chamber of a gas turbine engine based on image sequence analysis, comprising the following steps:
S1. acquiring flow field data inside a combustion chamber of a gas turbine engine, comprising the following steps:
S1.1 simulating a flow field of the combustion chamber by computational fluid dynamics;
S1.2 sampling a simulation process at an equal time interval to obtain a single frame image;
S2. preprocessing flow field images of the combustion chamber, comprising the following steps:
S2.1 conducting weighted average on the images, continuously taking a plurality of images in a small time interval, and using average results to characterize the image properties in the time period, with a calculation formula:
$$\overline{{I}_{t}} ( x , y ) = \frac{1}{N} {\sum }_{j = 1}^{N} {w}_{j} {I}_{j} ( x , y )$$
in the formula, N is number of observations; Iⱼ(x,y) is an instantaneously collected image at moment j; [symbol] (x,y) is an average image at moment t; and wⱼ is a weight coefficient and can be determined by Gaussian distribution;
S2.2 denoising the images obtained by weighted average, to obtain the flow field images;
S2.3 storing the denoised images in the form of a matrix and converting the images into floating point tensors to obtain an image set;
S2.4 labeling each image in the image set obtained in step S2.3 with “0” and “1” according to whether the flow field state of the image set is stable, with “0” representing instable and “1” representing normal, to construct a discrimination model data set;
S2.5 disrupting the order in the discrimination model data set and then dividing the discrimination model data set into a training set and a test set according to a ratio of 4:1;
S2.6 constructing the sample set using a window of size 129 on the image set obtained in step S2.3, and constructing a prediction model data set by using data falling in the window as a sample, using the first 128 data of each sample as input and using the last data as output;
S2.7 disrupting the order in the prediction model data set and then dividing the prediction model data set into a training set and a test set according to a ratio of 4:1;
S3. constructing a 3DWaveNet model as a generation network of a prediction model, comprising the following steps:
S3.1 adjusting the dimension of each sample as (n_steps,rows,cols,1) as input of the generation network; wherein n_steps is a time step, and n_steps=128, which is input data dimension of the prediction model data set obtained in step S2.6; rows indicates the number of rows of the images; cols indicates the number of columns of the images; the flow field images are black and white images, and the number of channels is 1;
S3.2 building a dilated convolution module based on causal convolution and dilated convolution, using 3D convolution to add a time dimension to capture and use residual connection to ensure that gradients do not disappear, introducing gated activation, reserving the features of each layer through skip connection and finally combining and outputting the features, and outputting a frame image;
S3.3 using a mean square error (MSE) as a loss function for training the network;
S4. constructing a discrimination network of the prediction model, comprising the following steps:
S4.1 to ensure that the discrimination network of the prediction model can process the data from the output of step S3.2, keeping the input dimension of the network consistent with the output dimension of step S3.2; conducting feature extraction using convolutional layers, and to ensure that the input of each layer of neural network has the same distribution, adding a batch standardization layer behind each convolutional layer;
S4.2 outputting a probability value using sigmoid function by a fully connected layer to characterize the probability that the input images are used as real images;
S4.3 using a binary cross entropy loss function as a loss function for training the network;
S5. combining the generation network and the discrimination network to form the prediction model, comprising the following steps:
S5.1 setting a discriminator to be untrainable; and after the input sample of the prediction model data set obtained in step S2.6 is input into a generator, inputting the generated images into the discrimination network to construct a prediction model network;
S5.2 training the prediction model network using the training set in the prediction model data set obtained in step S2.7, and assessing the model using the test set after the number of training is ended;
S6. constructing a discrimination model, comprising the following steps:
S6.1 taking the discrimination model data set obtained in step S2.4 as the input of the discrimination model, using the convolutional layers to extract image features, adding a maximum pooling layer to reduce the dimension of data while preserving the regional features of the images, and adding a dropout layer to avoid overfitting;
S6.2 using sigmoid function as an activation function to output a probability value to characterize whether the flow field of the combustion chamber is normal;
S6.3 using the training set obtained in step S2.5 to train the discrimination model, and using the test set to evaluate the discrimination model;
S6.4 finally inputting prediction images generated by the prediction model into the trained discrimination model to obtain a probability that the current state can operate normally.

2. The method for stability analysis of the combustion chamber of the gas turbine engine based on image sequence analysis according to claim 1, wherein 30 frames are sampled per second in the step S1.2.

3. The method for stability analysis of the combustion chamber of the gas turbine engine based on image sequence analysis according to claim 1, wherein the calculation formula of the loss function in the step S3.3 is as follows:
$${L}_{mse} = \frac{1}{Q} {\sum }_{n = 1}^{Q} {\sum }_{i = 1}^{rows} {\sum }_{j = 1}^{cols} {( {x}_{i , j}^{n} - )}^{2}$$
in the formula, Q is the number of training set samples, x_{i,j}ⁿ is a pixel value of point (i,j) on the nth real image, [symbol] is the nth image generated by generation network, and Lₘₛₑ is the loss function.
